(19) United States
(12) Patent Application Publication
(10) Pub. No.: US 2025/0194299 A1
(43) Pub. Date: Jun. 12, 2025

(54) NITRIDE SEMICONDUCTOR LIGHT-EMITTING ELEMENT

(71) Applicant: NIKKISO CO., LTD., Tokyo (JP)

(72) Inventors: Yusuke MATSUKURA, Ishikawa (JP); Cyril PERNOT, Ishikawa (JP); Kazufumi TAKAO, Ishikawa (JP)

(73) Assignee: NIKKISO CO., LTD., Tokyo (JP)

(21) Appl. No.: 18/971,110

(22) Filed: Dec. 6, 2024

(30) Foreign Application Priority Data
Dec. 7, 2023 (JP) 2023-206638

(51) Int. Cl. H10H 20/815; H10H 20/825

(52) U.S. Cl. CPC H10H 20/815; H10H 20/825

(57) ABSTRACT

A nitride semiconductor light-emitting element includes a substrate having a c-plane as a growth surface, a buffer layer formed on the growth surface, an n-type semiconductor layer formed on the buffer layer, an active layer being formed on the n-type semiconductor layer and emitting ultraviolet light at a central wavelength of not more than 365 nm, and a p-type semiconductor layer formed on the active layer. A film thickness of the buffer layer is more than 500 nm. An average oxygen concentration in the buffer layer satisfies not more than 4.5×10²¹ atoms/cm³.

### CROSS-REFERENCE TO RELATED APPLICATIONS

The present application is based on Japanese patent application No. 2023-206638 filed on Dec. 7, 2023, the entire contents of which are incorporated herein by reference.

### TECHNICAL FIELD

The present invention relates to a nitride semiconductor light-emitting element.

### BACKGROUND OF THE INVENTION

In Patent Literature 1, an oxygen concentration distribution in a buffer layer of a semiconductor light-emitting element having an emission peak wavelength of not less than 380 nm and not more than 425 nm is devised to improve crystalline quality of each semiconductor layer deposited on the buffer layer.
Citation List Patent Literature 1: WO 2019/044173

### SUMMARY OF THE INVENTION

It was newly found that nitride semiconductor light-emitting elements emitting ultraviolet light with a central wavelength of not more than 365 nm have a problem that oxygen contained in the buffer layer absorbs the ultraviolet light and this could cause a decrease in light output.

The invention was made in view of such circumstances and it is an object of the invention to provide a nitride semiconductor light-emitting element that can achieve improved light output.

To achieve the object described above, the invention provides a nitride semiconductor light-emitting element, comprising:
a substrate having a c-plane as a growth surface;
a buffer layer formed on the growth surface;
an n-type semiconductor layer formed on the buffer layer;
an active layer being formed on the n-type semiconductor layer and emitting ultraviolet light at a central wavelength of not more than 365 nm; and
a p-type semiconductor layer formed on the active layer,
wherein a film thickness of the buffer layer is more than 500 nm, and
wherein an average oxygen concentration in the buffer layer satisfies not more than 4.5×10²¹ atoms/cm³.

### Advantageous Effects of the Invention

According to the invention, it is possible to provide a nitride semiconductor light-emitting element that can achieve improved light output.

### BRIEF DESCRIPTION OF DRAWINGS

FIG. 1 is a schematic diagram illustrating a configuration of a nitride semiconductor light-emitting element in an embodiment.

FIG. 2 is a graph showing a relationship between average oxygen concentration in buffer layer and light output in Experimental Example.

FIG. 3 is a diagram illustrating a relationship between ratio of average oxygen concentration in buffer layer to average oxygen concentration in substrate and light output in Experimental Example.

### DETAILED DESCRIPTION OF THE INVENTION

### Embodiment

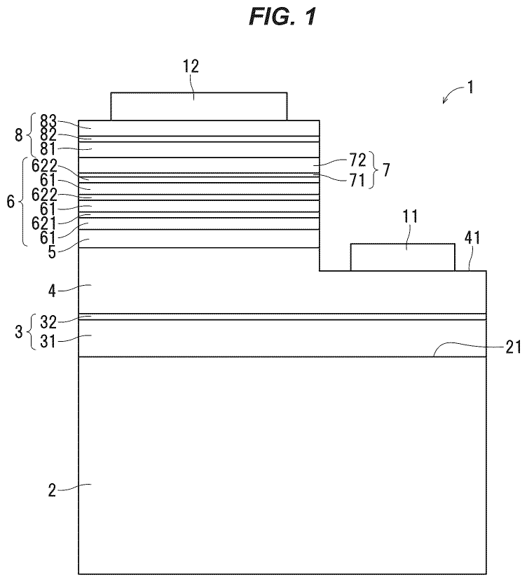

An embodiment of the invention will be described in reference to FIG. 1. The embodiment below is described as a preferred illustrative example for implementing the invention. Although some part of the embodiment specifically illustrates various technically preferable matters, the technical scope of the invention is not limited to such specific aspects.

### Nitride Semiconductor Light-Emitting Element 1

FIG. 1 is a schematic diagram illustrating a configuration of a nitride semiconductor light-emitting element 1. In FIG. 1, the scale ratio of each semiconductor layer of the nitride semiconductor light-emitting element 1 (hereinafter, also simply referred to as the “light-emitting element 1”) in a stacking direction is not necessarily the same as the actual scale ratio. Hereinafter, the direction of stacking each semiconductor layer of the light-emitting element 1 is referred to as the up-and-down direction. In addition, one side in the up-and-down direction, which is a side of a substrate 2 where each semiconductor layer is grown, (e.g., an upper side in FIG. 1) will be referred to as the upper side, and the opposite side (e.g., a lower side in FIG. 1) will be referred to as the lower side. In this regard, the terms “upper” and “lower” are used for descriptive purposes and do not limit the posture of the light-emitting element 1 with respect to the vertical direction when, e.g., the light-emitting element 1 is used.

The light-emitting element 1 constitutes, e.g., a light-emitting diode (LED) or a semiconductor laser (LD: laser diode). In the present embodiment, the light-emitting element 1 constitutes a light-emitting diode that emits light with a wavelength in an ultraviolet region. Particularly, the light-emitting element 1 in the present embodiment emits ultraviolet light at a central wavelength of not less than 240 nm and not more than 365 nm. The light-emitting element 1 can be used in fields such as, e.g., sterilization (e.g., air purification, water purification, etc.), medical treatment (e.g., light therapy, measurement/analysis, etc.), UV curing, etc.

The light-emitting element 1 includes a buffer layer 3, an n-type semiconductor layer 4, a composition gradient layer 5, an active layer 6, an electron blocking layer 7 and a p-type semiconductor layer 8 in this order on the substrate 2. The light-emitting element 1 also includes an n-side electrode 11 provided on the n-type semiconductor layer 4, and a p-side electrode 12 provided on the p-type semiconductor layer 8.

As semiconductors constituting the light-emitting element 1, it is possible to use, e.g., binary to quaternary group III nitride semiconductors expressed by AlₐGa_{b}In_{1-a-b}N (0≤a≤1, 0≤b≤1, 0≤a+b≤1). In the present embodiment, binary or ternary group III nitride semiconductors expressed by Al_{c}Ga_{1-c}N (0≤c≤1) are used as the semiconductors constituting the light-emitting element 1. These group III elements may be partially substituted with boron (B) or thallium (Tl), etc. In addition, nitrogen (N) may be partially substituted with phosphorus (P), arsenic (As), antimony (Sb) or bismuth (Bi), etc.

The substrate 2 is made of a material transparent to light emitted by the active layer 6. In the present embodiment, the substrate 2 is a sapphire (Al₂O₃) substrate. A growth surface 21 being an upper surface of the substrate 2 is a c-plane. This c-plane may have an off angle. The off angle of the substrate 2 is preferably not less than 0.6°. If the off angle of the substrate 2 is smaller than 0.6°, a terrace width of a step-and-terrace structure formed on the upper surface of the substrate 2 becomes wider and hillocks are likely to be formed on the upper surface of the buffer layer 3, which results in that oxygen is likely to be incorporated into the buffer layer 3. More preferably, the off angle of the substrate 2 is not less than 0.9° and not more than 1.1°. In addition, e.g., an aluminum nitride (AlN) substrate or an aluminum gallium nitride (AlGaN) substrate, etc. may alternatively be used as the substrate 2.

The buffer layer 3 is formed on the substrate 2. In the present embodiment, the buffer layer 3 is composed of two layers: an AlN layer 31 made of undoped aluminum nitride, and an AlGaN layer 32 made of undoped AlₚGa₁₋ₚN (0≤p≤1), in this order from the substrate 2 side. Undoped semiconductor layer means a semiconductor layer to which impurities are not intentionally added during formation of the semiconductor layer, and semiconductor layers containing trace amounts of inevitably included impurities are also regarded as undoped semiconductor layers. The overall film thickness of the buffer layer 3 is more than 500 nm. This makes it easier to reduce the lattice mismatch between the substrate 2 and the semiconductor layer formed on the buffer layer 3 and can improve the crystalline quality of the semiconductor layer formed on the buffer layer 3. The overall film thickness of the buffer layer 3 is preferably not more than 5 μm from the viewpoint of suppressing occurrence of cracks in the buffer layer 3. A film thickness of the AlN layer 31 is larger than a film thickness of the AlGaN layer 32. For example, the film thickness of the AlN layer 31 is not less than 380 nm and not more than 2200 nm, and the film thickness of the AlGaN layer 32 is not less than 80 nm and not more than 120 nm. An Al composition ratio p of the AlGaN layer 32 is, e.g., not less than 45% and not more than 65%. By the interposition of the AlGaN layer 32 between the AlN layer 31 and the n-type semiconductor layer 4, the difference in Al composition ratio between the buffer layer 3 and the n-type semiconductor layer 4 is reduced and the propagation of dislocations to the n-type semiconductor layer 4 is suppressed, resulting in improvement in conductivity of the n-type semiconductor layer 4.

In the light-emitting element 1 which emits ultraviolet light at a central wavelength of not more than 365 nm, if the average concentration of oxygen inevitably contained as an impurity in the buffer layer 3 is high, ultraviolet light emitted from the active layer 6 is absorbed by the oxygen in the buffer layer 3 and the light output of the light-emitting element 1 decreases. Therefore, the light-emitting element 1 in the present embodiment is configured such that the average oxygen concentration in the buffer layer 3 is not more than 4.5×10²¹ atoms/cm³. Hereinafter, the average oxygen concentration in the buffer layer 3 means an average value of the oxygen concentration along the up-and-down direction in the buffer layer 3. The average oxygen concentration in the buffer layer 3 is preferably not more than 1.0×10²¹ atoms/cm³, more preferably not more than 3.5×10²⁰ atoms/cm³, even more preferably not more than 3.0×10²⁰ atoms/cm³. Adjustment of the oxygen concentration in the buffer layer 3 can be achieved by, e.g., devising manufacturing conditions as described later.

Here, the sapphire substrate as the substrate 2 contains oxygen as a constituent element, and it is preferable that the average oxygen concentration in the buffer layer 3 is lower than an average oxygen concentration in the sapphire substrate. A ratio of the average oxygen concentration in the buffer layer 3 to the average oxygen concentration in the substrate 2 is preferably not more than 3/20, more preferably not more than 13/100, even more preferably not more than 13/1000, and further preferably not more than 1/100.

The buffer layer 3 may be a single layer or may be composed of not less than three layers. When the substrate 2 is an aluminum nitride substrate or an aluminum gallium nitride substrate, the buffer layer 3 may be composed of, e.g., only the AlGaN layer 32.

The n-type semiconductor layer 4 is formed on the buffer layer 3. The n-type semiconductor layer 4 is, e.g., an n-type cladding layer made of Al_{q}Ga_{1-q}N (0≤q≤1) doped with an n-type impurity. In the present embodiment, silicon (Si) is used as the n-type impurity. The same applies to the semiconductor layers containing an n-type impurity other than the n-type semiconductor layer 4. Alternatively, germanium (Ge), selenium (Se) or tellurium (Te), etc. may be used as the n-type impurity. An Al composition ratio q of the n-type semiconductor layer 4 is, e.g., not less than 45% and not more than 65%. The n-type semiconductor layer 4 may have a single-layer structure or may have a multilayer structure.

The composition gradient layer 5 is formed on the n-type semiconductor layer 4. The composition gradient layer 5 is made of AlᵣGa₁₋ᵣN (0≤r≤1). In the composition gradient layer 5, an Al composition ratio in the up-and-down direction is higher at an upper position. The composition gradient layer 5 may have, e.g., a very small region in the up-and-down direction (e.g., a region of not more than 5% of the entire composition gradient layer 5 in the up-and-down direction) in which the Al composition ratio does not increase toward the upper side.

The Al composition ratio of a lower end portion of the composition gradient layer 5 is preferably substantially the same (e.g., a difference within 5%) as an Al composition ratio of an upper portion of the n-type semiconductor layer 4 that is adjacent to the composition gradient layer 5 on the lower side. In addition, the Al composition ratio of an upper end portion of the composition gradient layer 5 is preferably substantially the same (e.g., a difference within 5%) as an Al composition ratio of a lower portion of a barrier layer 61 that is adjacent to the composition gradient layer 5 on the upper side.

The active layer 6 is formed on the composition gradient layer 5. The active layer 6 in the present embodiment has a multiple quantum well structure which includes plural well layers 621, 622. A band gap of the active layer 6 is adjusted so that ultraviolet light at a central wavelength of not less than 240 nm and not more than 365 nm can be emitted. When the active layer 6 has a multiple quantum well structure as in the present embodiment, the central wavelength of ultraviolet light emitted by the active layer 6 is preferably not less than 250 nm and not more than 320 nm, more preferably, not less than 260 nm and not more than 290 nm from the viewpoint of improving light output. In the present embodiment, the active layer 6 has three barrier layers 61 and three well layers 621, 622 which are alternately stacked. In the active layer 6, the barrier layer 61 is located at the lower end and the well layer 622 is located at the upper end.

Each barrier layer 61 is made of AlₛGa₁₋ₛN (0<s≤1). An Al composition ratio of each barrier layer 61 is, e.g., not less than 75% and not more than 95%. Each barrier layer 61 has a film thickness of, e.g., not less than 2 nm and not more than 50 nm.

The well layers 621, 622 are made of AlₜGa₁₋ₜN (0<t<1). An Al composition ratio t of each of the well layers 621, 622 is smaller than the Al composition ratio s of the barrier layers 61 (i.e., t<s).

The three well layers 621, 622 are configured such that the lowermost well layer 621, which is the well layer arranged on the lowermost side, has a different configuration from the upper-side well layers 622 which are two well layers other than the lowermost well layer 621. For example, a film thickness of the lowermost well layer 621 is not less than 1 nm greater than a film thickness of each of the two upper-side well layers 622 and the Al composition ratio of the lowermost well layer 621 is not less than 2% greater than the Al composition ratio of each of the two upper-side well layers 622. In the present embodiment, the upper-side well layers 622 have a film thickness of not less than 2 nm and not more than 4 nm and an Al composition ratio of not less than 25% and not more than 45%, and the lowermost well layer 621 has a film thickness of not less than 4 nm and not more than 6 nm and an Al composition ratio of not less than 35% and not more than 55%. A difference between the film thickness of the lowermost well layer 621 and the film thickness of each upper-side well layer 622 can be not less than 2 nm and not more than 4 nm.

By increasing the Al composition ratio of the lowermost well layer 621 to higher than the Al composition ratio of the upper-side well layers 622, crystalline quality of the lowermost well layer 621 is improved. This is because the difference in the Al composition ratio between the lowermost well layer 621 and the n-type semiconductor layer 4 is reduced. The improved crystalline quality of the lowermost well layer 621 improves crystalline quality of each semiconductor layer formed on and above the lowermost well layer 621 in the active layer 6. As a result, carrier mobility in the active layer 6 is improved and light output is improved. Such effects are more pronounced when the lowermost well layer 621 has a larger film thickness, but the film thickness of the lowermost well layer 621 is designed to be not more than a predetermined value from the viewpoint of suppressing an increase in the electrical resistance value of the entire light-emitting element 1.

Although the example in which the active layer 6 has a multiple quantum well structure with the three well layers 621, 622 has been described in the present embodiment, it is not limited thereto. The active layer 6 may have a multiple quantum well structure with two or not less than four well layers 621, 622. Alternatively, the active layer 6 may have a single quantum well structure having only one well layer 621, 622.

The electron blocking layer 7 is formed on the active layer 6. The electron blocking layer 7 serves to improve efficiency of electron injection into the active layer 6 by suppressing occurrence of the overflow phenomenon in which electrons leak from the active layer 6 to the p-type semiconductor layer 8 side (hereinafter, also referred to as the electron blocking effect). The electron blocking layer 7 has a stacked structure in which a first layer 71 and a second layer 72 are stacked in this order from the lower side.

The first layer 71 is provided on the active layer 6. The first layer 71 is made of, e.g., AlᵤGa₁₋ᵤN (0<u≤1). An Al composition ratio n of the first layer 71 is, e.g., not less than 90% and is made of aluminum nitride in the present embodiment. A film thickness of the first layer 71 is, e.g., not less than 0.5 nm and not more than 5.0 nm.

The second layer 72 is made of, e.g., AlᵥGa₁₋ᵥN (0<v<1). An Al composition ratio v of the second layer 72 is smaller than the Al composition ratio u of the first layer 71 (i.e., v<u) and is, e.g., not less than 70% and not more than 90%. A film thickness of the second layer 72 is larger than the film thickness of the first layer 71 and is, e.g., not less than 15 nm and not more than 100 nm.

When the first layer 71 with a relatively high Al composition ratio has an excessively large film thickness, it causes an excessive increase in the electrical resistance value of the entire light-emitting element 1 since a semiconductor layer with a higher Al composition ratio has a higher electrical resistance value. For this reason, the film thickness of the first layer 71 is preferably small to some extent. On the other hand, if the film thickness of the first layer 71 is reduced, it increases the probability that electrons pass through the first layer 71 from the lower side to the upper side due to the tunnel effect. Therefore, in the light-emitting element 1 of the present embodiment, the second layer 72 is formed on the first layer 71 to suppress passage of electrons through the entire electron blocking layer 7.

Each of the first layer 71 and the second layer 72 can be an undoped layer, a layer containing an n-type impurity, a layer containing a p-type impurity, or a layer containing both an n-type impurity and a p-type impurity. Magnesium (Mg) can be used as the p-type impurity, but zinc (Zn), beryllium (Be), calcium (Ca), strontium (Sr), barium (Ba) or carbon (C), etc. may be used other than magnesium. The same applies to the other semiconductor layers containing a p-type impurity. When each electron blocking layer 7 contains an impurity, the impurity in each electron blocking layer 7 may be contained in the entire portion of each electron blocking layer 7 or may be contained in a part of each electron blocking layer 7.

The p-type semiconductor layer 8 is formed on the electron blocking layer 7. The p-type semiconductor layer 8 has a lower Al composition ratio than that of the electron blocking layer 7 and is made of Al_{w}Ga_{1-w}N (0≤w≤1) doped with a p-type impurity. In the present embodiment, the p-type semiconductor layer 8 has a stacked structure in which a first p-type cladding layer 81, a second p-type cladding layer 82 and a p-type contact layer 83 are stacked in this order from the lower side.

The first p-type cladding layer 81 is provided so as to be in contact with the second layer 72. The first p-type cladding layer 81 is made of AlₓGa₁₋ₓN (0<x≤1) containing a p-type impurity. An Al composition ratio x of the first p-type cladding layer 81 is, e.g., not less than 45% and not more than 65%. A film thickness of the first p-type cladding layer 81 is, e.g., not less than 15 nm and not more than 35 nm.

The second p-type cladding layer 82 is made of Al_{y}Ga_{1-y}N (0<y≤1) containing a p-type impurity. In the second p-type cladding layer 82, an Al composition ratio in the up-and-down direction decreases toward the upper side. In this regard, the second p-type cladding layer 82 may have a very small region in the stacking direction (e.g., a region of not more than 5% of the entire second p-type cladding layer 82 in the stacking direction) in which the Al composition ratio does not decrease toward the upper side.

The second p-type cladding layer 82 is preferably configured such that the Al composition ratio at its lower end portion is substantially the same (e.g., a difference within 5%) as the Al composition ratio of the first p-type cladding layer 81 and the Al composition ratio at its upper end portion is substantially the same (e.g., a difference within 5%) as an Al composition ratio of the p-type contact layer 83. A film thickness of the second p-type cladding layer 82 can be, e.g., not less than 2 nm and not more than 4 nm.

The p-type contact layer 83 is a layer connected to the p-side electrode 12 (described later) and is doped with a high concentration of a p-type impurity. The p-type contact layer 83 is configured to have a low Al composition ratio (e.g., not more than 10%) to achieve an ohmic contact with the p-side electrode 12, and from such a viewpoint, the p-type contact layer 83 is preferably made of p-type gallium nitride (GaN). A film thickness of the p-type contact layer 83 is, e.g., not less than 10 nm and not more than 25 nm. The n-type semiconductor layer 8 may be a single layer or may be composed of plural layers.

The n-side electrode 11 is formed on an exposed surface 41 of the n-type semiconductor layer 4 which is exposed from the active layer 6 on the upper side. The n-side electrode 11 can be, e.g., a multilayered film formed by sequentially stacking titanium (Ti), aluminum, titanium and titanium nitride (TiN) on the n-type semiconductor layer 4. When the light-emitting element 1 is flip-chip mounted as described below, the n-side electrode 11 may be composed of a material that can reflect ultraviolet light emitted by the active layer 6.

The p-side electrode 12 is formed on an upper surface of the p-type semiconductor layer 8. The p-side electrode 12 can be made of, e.g., rhodium (Rh). In the present embodiment, the p-side electrode 12 is, but not limited to, a reflective electrode that has a reflectance of not less than 50%, preferably not less than 60%, at the central wavelength of light emitted by the active later 6.

The light-emitting element 1 is used in a state of being flip-chip mounted on a package substrate (not shown). That is, the light-emitting element 1 is mounted such that a side in the up-and-down direction, which is a side where the n-side electrode 11 and the p-side electrode 12 are provided, faces the package substrate and each of the n-side electrode 11 and the p-side electrode 12 is attached to the package substrate via a connection member such as gold bump. Light from the flip-chip mounted light-emitting element 1 is extracted on the substrate 2 side (i.e., on the lower side).

Method for manufacturing Nitride semiconductor light-emitting element 1 Next, an example of a method for manufacturing the light-emitting element 1 in the present embodiment will be described.

In the present embodiment, the buffer layer 3, the n-type semiconductor layer 4, the composition gradient layer 5, the active layer 6, the electron blocking layer 7 and the p-type semiconductor layer 8 are epitaxially grown on the disc-shaped substrate 2 in this order by the Metal Organic Chemical Vapor Deposition (MOCVD) method. That is, in the present embodiment, the disc-shaped substrate 2 is placed in a chamber and each semiconductor layer is formed on the substrate 2 by introducing source gases of each semiconductor layer to be formed on the substrate 2 into the chamber. As the source gases to epitaxially grow each semiconductor layer, it is possible to use trimethylaluminum (TMA) as an aluminum source, trimethylgallium (TMG) as a gallium source, ammonia (NH₃) as a nitrogen source, tetramethylsilane (TMSi) as a silicon source, and biscyclopentadienylmagnesium (Cp₂Mg) as a magnesium source.

The MOCVD method is sometimes called the Metal Organic Vapor Phase Epitaxy (MOVPE) method. From the viewpoint of forming the buffer layer 3 with a film thickness of more than 500 nm on the substrate 2, it is preferable to use an epitaxial growth method such as the MOCVD method, the Hydride Vapor Phase Epitaxy (HVPE) method, or the Physical Vapor Transport (PVT) method. In the present embodiment, the sputtering method is not used to grow the buffer layer 3. It is difficult to deposit the buffer layer 3 with a film thickness of more than 500 nm by the sputtering method. However, the sputtering method may be used if the buffer layer 3 with a film thickness of more than 500 nm can be deposited by the sputtering method.

In the method for manufacturing the light-emitting element 1 in the present embodiment, the manufacturing conditions are designed so that the oxygen concentration in the buffer layer 3 is low as described above. For example, when evacuating the chamber to a relatively high degree of vacuum before depositing each semiconductor layer on the substrate 2, oxygen is less likely to be contained in the buffer layer 3 to be deposited. Meanwhile, depending on the material of the chamber wall surface facing the space inside the chamber, oxygen may be generated from the wall surface in a high-temperature environment at the film deposition temperature of the buffer layer, hence, the material of the chamber wall surface could also affect the oxygen concentration in the buffer layer 3. As shown in the above examples, the oxygen concentration in the buffer layer 3 can be adjusted by appropriately designing the manufacturing conditions that can affect the oxygen concentration in the buffer layer 3.

After forming each semiconductor layer on the disc-shaped substrate 2, a mask is formed on a portion of the p-type semiconductor layer 8, i.e., a part other than the portion to be the exposed surface 41 of the n-type semiconductor layer 4. Then, the region in which the mask is not formed is removed by etching from the upper surface of the p-type semiconductor layer 8 to the middle of the n-type semiconductor layer 4 in the up-and-down direction. The exposed surface 41 exposed upward is thereby formed on the n-type semiconductor layer 4. After forming the exposed surface 41, the mask is removed.

Subsequently, the n-side electrode 11 is formed on the exposed surface 41 of the n-type semiconductor layer 4 and the p-side electrode 12 is formed on the p-type semiconductor layer 8. The n-side electrode 11 and the p-side electrode 12 may be formed by, e.g., a well-known method such as the electron beam evaporation method or the sputtering method. The object completed through the above process is cut into pieces with a desired dimension. Plural light-emitting elements 1 as shown in FIG. 1 are thereby obtained from one wafer.

### Functions and Effects of the Embodiment

The light-emitting element 1 of the present embodiment is configured such that the active layer 6 emits ultraviolet light at a central wavelength of not more than 365 nm and the film thickness of the buffer layer 3 is more than 500 nm. In case of having such a configuration, it is easy to reduce the lattice mismatch between the substrate 2 and the n-type semiconductor layer 4 by the buffer layer 3 with a relatively large film thickness, but the problem of a decrease in the light output of the light-emitting element 1 due to absorption of ultraviolet light by oxygen contained in the buffer layer 3 tends to become prominent. For this reason, in the present embodiment, the average oxygen concentration in the buffer layer 3 is set to not more than 4.5×10²¹ atoms/cm³. It is thereby possible to improve the light output of the light-emitting element 1. This numerical value is supported by Experimental Example described later. In addition, since the growth surface 21 of the substrate 2 is a c-plane, the oxygen concentration in the buffer layer 3 formed on substrate 2 is reduced compared to when the growth surface 21 is an r-plane, etc.

In addition, the average oxygen concentration in the buffer layer 3 further satisfies not more than 1.0×10²¹ atoms/cm³. It is thereby possible to further improve the light output of the light-emitting element 1.

In addition, the substrate 2 is a sapphire substrate, and the average oxygen concentration in the buffer layer 3 is lower than the average oxygen concentration in the substrate 2. In this way, by making the average oxygen concentration in the buffer layer 3 lower than the average oxygen concentration in the sapphire substrate which contains oxygen as a constituent element, it is possible to further improve the light output of the light-emitting element 1.

In addition, the ratio of the average oxygen concentration in the buffer layer 3 to the average oxygen concentration in the substrate 2 satisfies not more than 3/20. It is thereby possible to further improve the light output of the light-emitting element 1.

The ratio of the average oxygen concentration in the buffer layer 3 to the average oxygen concentration in the substrate 2 further satisfies not more than 13/100. It is thereby possible to further improve the light output of the light-emitting element 1.

As described above, according to the present embodiment, it is possible to provide a nitride semiconductor light-emitting element that can achieve improved light output.

### Experiment Example

This Experimental Example is an example of evaluating a relationship between average oxygen concentration in buffer layer and light output of wafer. Among the names of the constituent elements used in this Experimental Example, the constituent elements denoted by the same names as those used in the already-described embodiment indicate the same constituent elements as those in the already-described embodiment, unless otherwise specified.

First, wafers as Samples 1 to 4 will be described using Table 1. Samples 1 to 4 are wafers having the same basic configuration as the light-emitting element in the embodiment, unless otherwise specified.

TABLE 1

| | | | | Average oxygen |
|---|---|---|---|---|
| | | | Al composition | concentration |
| Structure | | Film thickness | ratio [%] | [atoms/cm³] |
| Substrate | | 430 ± 25 [um] | — | Sample 1: 3.21E+22 |
| | | | | Sample 2: 3.16E+22 |
| | | | | Sample 3: 2.95E+22 |
| | | | | Sample 4: 3.20E+22 |
| Buffer layer | AlN layer | Sample 1: 670 [nm] | 100 | Sample 1: 4.97E+21 |
| | | Sample 2: 630 [nm] | | Sample 2: 4.34E+21 |
| | | Sample 3: 450 [nm] | | Sample 3: 3.31E+20 |
| | | Sample 4: 2000 [nm] | | Sample 4: 1.08E+20 |
| | AlGaN layer | 80 [nm] | 55 ± 10 | — |
| n-type semiconductor layer | | 2000 ± 200 [nm] | 55 ± 10 | |
| Composition gradient layer | | 15 ± 5 [nm] | 55→85 | |
| Active layer | Barrier layer | 7 ± 5 [nm] | 85 ± 10 | |
| (3QW) | Well layer | 5 ± 1 [nm] | 45 ± 10 | |
| | (Lowermost well | | | |
| | layer) | | | |
| | Barrier layer | 7 ± 5 [nm] | 85 ± 10 | |
| | Well layer (Upper- | 3 ± 1 [nm] | 35 ± 10 | |
| | side well layer) | | | |
| | Barrier layer | 7 ± 5 [nm] | 85 ± 10 | |
| | Well layer (Upper- | 3 ± 1 [nm] | 35 ± 10 | |
| | side well layer) | | | |
| Electron | First layer | 1.5 ± 1 [nm] | 95 ± 5 | |
| blocking layer | Second layer | 25 ± 10 [nm] | 80 ± 10 | |
| P-type | First p-type | 25 ± 10 [nm] | 55 ± 10 | |
| semiconductor | cladding layer | | | |
| layer | Second p-type | 3 ± 1 [nm] | 55→0 | |
| | cladding layer | | | |
| | p-type contact | 20 ± 5 [nm] | 0 | |
| | layer | | | |

As shown in Table 1, Samples 1 to 4 differ from one another in the average oxygen concentration in the buffer layer and the film thickness of the AlN layer of the buffer layer. In this regard, the average oxygen concentrations in the substrates of Samples 1 to 4 are slightly different from one another but are not intentionally changed and it is within the range of individual differences.

In Table 1, the configurations common to Samples 1 to 4 are shown without distinguishing between Samples 1 to 4, and each of the film thickness of the AlN layer, the average oxygen concentration in the substrate and the average oxygen concentration in the AlN layer is shown for each of Samples 1 to 4. The Al composition ratio of each layer shown in Table 1 is a value estimated from secondary ion intensity of Al measured by secondary ion mass spectrometry (SIMS). In addition, the figure in the column for Composition gradient layer in Table 1 indicates that the Al composition ratio of the composition gradient layer in the up-and-down direction gradually increases from 55% to 85% from the lower end to the upper end of the composition gradient layer. Likewise, the figure in the column for Second p-type cladding layer in Table 1 indicates that the Al composition ratio of the second p-type cladding layer in the up-and-down direction gradually decreases from 55% to 0% from the lower end to the upper end of the second p-type cladding layer.

The average oxygen concentration in each layer shown in Table 1 was calculated from measurement values by SIMS. The oxygen concentrations in the substrate and the AlN layer of each sample were measured using a wafer grown up to the AlN layer under the same manufacturing conditions as those used to make each sample. The value of the oxygen concentration of each layer of the above-mentioned wafer measured by SIMS was the result when the wafer was measured from above. The AlGaN layer constituting the buffer layer has a small film thickness and it is difficult to measure its oxygen concentration accurately, but it is expected to be equivalent to the oxygen concentration in the AlN layer. The oxygen concentration in the buffer layer can vary depending on the manufacturing environment (i.e., the temperature in the chamber, or the material of the chamber wall surface, etc.) as mentioned above, but in this Experimental Example, the AlN layer and the AlGaN layer of each sample were made in the same manufacturing environment and the oxygen concentration in the AlN layer is regarded as the same as that in the AlGaN layer. In other words, in this Experimental Example, the oxygen concentration in the AlN layer shown in Table 1 is regarded as the oxygen concentration in the entire buffer layer.

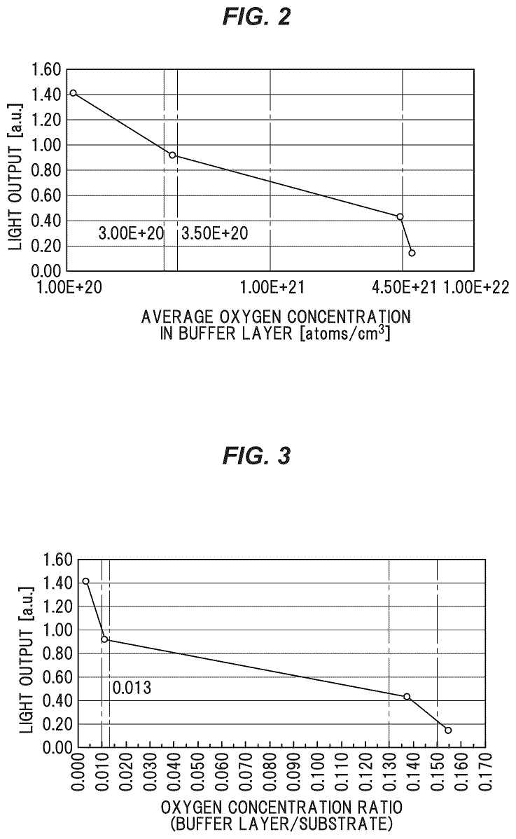

Then, the light output of each of Samples 1 to 4 was measured by applying a current of 20 mA in the on-wafer state. The light output of each sample was measured by a photodetector placed under each sample (i.e., placed on the substrate side). The results are shown in FIG. 2. FIG. 2 is a graph showing a relationship between average oxygen concentration in buffer layer and light output.

As understood from FIG. 2, as the average oxygen concentration in the buffer layer increases, the light output gradually decreases up to the average oxygen concentration in the buffer layer of 4.5×10²¹ atoms/cm³ but rapidly decreases once the average oxygen concentration becomes more than 4.5×10²¹ atoms/cm³. Therefore, the average oxygen concentration in the buffer layer is preferably not more than 4.5×10²¹ atoms/cm³. As also understood from FIG. 2, the average oxygen concentration in the buffer layer is preferably not more than 1.0×10²¹ atoms/cm³, more preferably not more than 3.5×10²⁰ atoms/cm³, even more preferably not more than 3.0×10²⁰ atoms/cm³, from the viewpoint of improving the light output.

The result shown in FIG. 2 will be examined also from a different perspective using Table 2 and FIG. 3. Table 2 shows the average oxygen concentration in the substrate, the average oxygen concentration in the buffer layer, the ratio of the average oxygen concentration in the buffer layer to the average oxygen concentration in the substrate (hereinafter referred to as the “oxygen concentration ratio”) and the light output result for each sample. FIG. 3 is a diagram illustrating a relationship between the oxygen concentration ratio and the light output.

TABLE 2

| | Average oxygen concentration | | Oxygen concen- | |
|---|---|---|---|---|
| | [atoms/cm³] | | tration ratio | Light |
| | | Buffer | (Buffer layer/ | output |
| Sample | Substrate | layer | Substrate) | [a.u.] |
| Sample 1 | 3.21E+22 | 4.97E+21 | 0.155 | 0.14 |
| Sample 2 | 3.16E+22 | 4.34E+21 | 0.137 | 0.43 |
| Sample 3 | 2.95E+22 | 3.31E+20 | 0.011 | 0.92 |
| Sample 4 | 3.20E+22 | 1.08E+20 | 0.003 | 1.41 |

As understood from Table 2 and FIG. 3, the oxygen concentration ratio is preferably not more than 0.150 (i.e., not more than 3/20), more preferably not more than 0.130 (i.e., not more than 13/100), even more preferably not more than 0.013 (i.e., not more than 13/1000), and even further preferably not more than 0.010 (i.e., not more than 1/100).

### Summary of the Embodiment

Technical ideas understood from the embodiment will be described below citing the reference signs, etc., used for the embodiment. However, each reference sign, etc., described below is not intended to limit the constituent elements in the claims to the members, etc., specifically described in the embodiment.

The first feature of the invention is a nitride semiconductor light-emitting element 1 comprising: a substrate 2 having a c-plane as a growth surface 21; a buffer layer 3 formed on the growth surface 21; an n-type semiconductor layer 4 formed on the buffer layer 3; an active layer 6 being formed on the n-type semiconductor layer 4 and emitting ultraviolet light at a central wavelength of not more than 365 nm; and a p-type semiconductor layer 8 formed on the active layer 6, wherein a film thickness of the buffer layer 3 is more than 500 nm, and wherein an average oxygen concentration in the buffer layer 3 satisfies not more than 4.5×10²¹ atoms/cm³.

It is thereby possible to improve the light output of the nitride semiconductor light-emitting element 1.

The second feature of the invention is that, in the first feature, the average oxygen concentration in the buffer layer 3 further satisfies not more than 1.0×10²¹ atoms/cm³. It is thereby possible to further improve the light output of the nitride semiconductor light-emitting element 1.

The third feature of the invention is that, in the first or second feature, the substrate 2 comprises a sapphire substrate, and the average oxygen concentration in the buffer layer 3 is lower than an average oxygen concentration in the substrate 2.

It is thereby possible to further improve the light output of the nitride semiconductor light-emitting element 1.

The fourth feature of the invention is that, in the third feature, a ratio of the average oxygen concentration in the buffer layer 3 to the average oxygen concentration in the substrate 2 satisfies not more than 3/20.

It is thereby possible to further improve the light output of the nitride semiconductor light-emitting element 1.

The fifth feature of the invention is that, in the fourth feature, the ratio of the average oxygen concentration in the buffer layer 3 to the average oxygen concentration in the substrate 2 further satisfies not more than 13/100.

It is thereby possible to further improve the light output of the nitride semiconductor light-emitting element 1.

### Additional Note

Although the embodiment of the invention has been described, the invention according to claims is not to be limited to the embodiment described above. Further, please note that not all combinations of the features described in the embodiment are necessary to solve the problem of the invention. In addition, the invention can be appropriately modified and implemented without departing from the gist thereof. For example, a configuration in which the configurations of the above-described embodiment are appropriately combined may be adopted.

1. A nitride semiconductor light-emitting element, comprising:
a substrate having a c-plane as a growth surface;
a buffer layer formed on the growth surface;
an n-type semiconductor layer formed on the buffer layer;
an active layer being formed on the n-type semiconductor layer and emitting ultraviolet light at a central wavelength of not more than 365 nm; and
a p-type semiconductor layer formed on the active layer,
wherein a film thickness of the buffer layer is more than 500 nm, and
wherein an average oxygen concentration in the buffer layer satisfies not more than 4.5×10²¹ atoms/cm³.

2. The nitride semiconductor light-emitting element according to claim 1, wherein the average oxygen concentration in the buffer layer further satisfies not more than 1.0×10²¹ atoms/cm³.

3. The nitride semiconductor light-emitting element according to claim 1, wherein the substrate comprises a sapphire substrate, and wherein the average oxygen concentration in the buffer layer is lower than an average oxygen concentration in the substrate.

4. The nitride semiconductor light-emitting element according to claim 3, wherein a ratio of the average oxygen concentration in the buffer layer to the average oxygen concentration in the substrate satisfies not more than 3/20.

5. The nitride semiconductor light-emitting element according to claim 4, wherein the ratio of the average oxygen concentration in the buffer layer to the average oxygen concentration in the substrate further satisfies not more than 13/100.
